(19) United States
(12) Patent Application Publication
(10) Pub. No.: US 2012/0286377 A1
(43) Pub. Date: Nov. 15, 2012

(54) Nanoelectromechanical Structures Exhibiting Tensile Stress And Techniques For Fabrication Thereof

(75) Inventors: Josephine B. Chang, Mahopac, NY (US); Sebastian U. Engelmann, White Plains, NY (US); Michael A. Guillorn, Yorktown Heights, NY (US); Fei Liu, Yorktown Heights, NY (US); Conal E. Murray, Yorktown Heights, NY (US)

(73) Assignee: International Business Machines Corporation, Armonk, NY (US)

(21) Appl. No.: 13/103,193

(22) Filed: May 9, 2011

(51) Int. Cl. H01L 29/84; H01L 21/3105; H01L 29/06

(52) U.S. Cl. 257/415; 257/618; 438/791; 257/E29.022; 257/E21.241; 257/E29.324

(57) ABSTRACT

Improved nano-electromechanical system devices and structures and systems and techniques for their fabrication. In one embodiment, a structure comprises an underlying substrate separated from first and second anchor points by first and second insulating support points, respectively. The first and second anchor points are joined by a beam. First and second deposition regions overlie the first and second anchor points, respectively, and the first and second deposition regions exert compression on the first and second anchor points, respectively. The compression on the first and second anchor points causes opposing forces on the beam, subjecting the beam to a tensile stress. The first and second deposition regions suitably exhibit an internal tensile stress having an achievable maximum varying with their thickness, so that the tensile stress exerted on the beam depends at least on part on the thickness of the first and second deposition regions.

### FIELD OF THE INVENTION

The present invention relates generally to nanoelectromechanical (NEMS) devices and their fabrication. More particularly, the invention relates to improved nanoelectromechanical devices exhibiting tensile stress and techniques for fabricating such devices

### BACKGROUND

The latter part of the twentieth century and the early part of the twenty-first century have seen growing interest in small-scale systems, with increasing interest in and development of technologies such as micro-electromechanical systems (MEMS) and nano-electromechanical systems (NEMS). Micro-electromechanical systems typically comprise structures having dimensions of less than 100 microns, while nano-electromechanical systems typically comprise structures having dimensions of less than 100 nanometers. Continuing advances in fabrication techniques have led to greatly increased interest in and ability to create NEMS devices. NEMS devices have drawn considerable interest because their small size yields a number of advantages, such as the availability of quantum effects, very high ratios of surface area to volume and mass, and the ability to operate at extremely high frequencies. High frequency operation is valuable in systems such as sensors, finding use in systems such as resonant transducers or signal processing where NEMS may form a passive filter or mixing element. Particular advantages of high frequency operation are a lower viscous damping from air and thus lower energy loss, as well as higher frequency resolution leading to greater sensing sensitivity and a greater signal to noise ratio.

Sensing and transducer applications also benefit greatly from a high quality factor, or Q factor. The Q factor of an oscillator or resonator is a dimensionless parameter indicating how underdamped the oscillator or resonator is, or, equivalently, characterizes a resonator's bandwidth relative to its center frequency. A higher Q factor indicates a lower rate of energy loss relative to the stored energy of the oscillator or resonator. If an oscillator or resonator characterized by a high Q factor is subjected to an input causing oscillation, the oscillation will continue for a longer time than for an oscillator or resonator characterized by a lower Q factor.

### BRIEF SUMMARY

In a first embodiment, the invention comprises a structure. The structure comprises a beam extending between first and second anchor points. The structure further comprises a deposition region overlying the first anchor point and a second deposition region overlying the second anchor point. The first and second deposition regions exert a compressive force on the first and second anchor points, respectively, such that each of the first and second anchor points exerts a force on the beam. The forces exerted by the first and second anchor points combine to subject the beam to a tensile stress.

In a second embodiment, the invention comprises a process of fabrication of a device. The process comprises depositing an active semiconductor layer on a substrate, depositing a deposition layer on the semiconductor layer, and removing portions of the deposition layer so as to form a desired pattern in the deposition layer. The process further comprises removing portions of the semiconductor layer and the substrate to form a pattern of the semiconductor layer and the substrate conforming to the pattern of the deposition layer, and removing a portion of the deposition layer such that portions of the deposition layer remaining on the semiconductor layer exhibit internal tensile stress so as to subject each of first and second regions of the semiconductor layer to a compressive stress. The process further comprises removing a portion of the substrate such that a first and second anchor point of the semiconductor layer are connected by a beam subjected to tensile stress by the first and second regions of the semiconductor layer.

In a third embodiment, the invention comprises a resonant transducer. The transducer comprises an underlying silicon layer, first and second insulating support points overlying the underlying silicon layer, and first and second active silicon anchor points overlying the first and second insulating support points, respectively. The transducer further comprises an active silicon beam joining the first and second active silicon anchor points and first and second deposition regions disposed to exert a compressive force on the anchor points such that the anchor points exert opposing forces on the active silicon beam to subject the active silicon beam to a tensile stress.

These and other embodiments and aspects are detailed below with particularity.

### BRIEF DESCRIPTION OF THE SEVERAL VIEWS OF THE DRAWINGS

FIG. 1 illustrates a silicon on insulator beam suitable for use in devices according to embodiments of the present invention;

FIG. 2 illustrates an exemplary device according to an embodiment of the present invention;

FIG. 3 illustrates a process of fabrication of a device according to an embodiment of the present invention;

FIG. 4A illustrates a silicon on insulator substrate comprising an initial stage of fabrication of a device according to an embodiment of the present invention;

FIG. 4B illustrates a further stage of fabrication, showing a silicon nitride layer overlying the substrate;

FIG. 4C illustrates a further stage of fabrication, showing the silicon nitride layer patterned to a desired shape;

FIG. 4D illustrates a further stage of fabrication, showing an active silicon layer of the substrate patterned to conform to the shape of the silicon nitride layer;

FIG. 4E illustrates a further stage of fabrication, showing patterning of an underlying layer of the substrate;

FIG. 4F illustrates a further stage of fabrication removal of a silicon nitride bridge of the silicon nitride layer to leave deposition regions overlying portions of the patterned active silicon layer;

FIG. 4G illustrates a further stage of fabrication, after removal of a bridge of the underlying layer of the substrate to free an active silicon beam;

FIG. 4H illustrates a further stage of fabrication, showing a structure similar to the structure of FIG. 4F, but comprising deposition regions exhibiting an increased thickness as compared to the deposition regions of FIG. 4F.

FIG. 5A illustrates an initial stage of fabrication of a device according to an embodiment of the present invention, showing an underlying silicon layer, an insulating layer, and an active silicon layer;

FIG. 5B illustrates a further stage of fabrication, showing an upper oxide layer overlying the active silicon layer;

FIG. 5C illustrates a further stage of fabrication, showing receptacles extending through the upper oxide layer and into the active silicon layer;

FIG. 5D illustrates a further stage of fabrication, showing embedded silicon carbon deposition regions placed in the receptacles;

FIG. 5E illustrates a further stage of fabrication, showing a silicon nitride layer overlying the upper oxide layer and extending into the receptacles;

FIG. 5F illustrates a further stage of fabrication, after removal of portions of the silicon nitride layer;

FIG. 5G illustrates a further stage of fabrication, after removal of portions of the upper oxide layer;

FIG. 5H illustrates a further stage of fabrication, after removal of portions of the active silicon layer;

FIG. 5I illustrates a further stage of fabrication, after removal of portions of the underlying silicon layer;

FIG. 5J illustrates a further stage of fabrication, after removal of portions of a silicon nitride bridge to leave silicon nitride deposition regions, and removal of a portion of the insulating oxide layer;

FIG. 5K illustrates a further stage of fabrication, after removal of a portion of the upper oxide layer extending between the silicon nitride deposition regions; and

FIG. 6 illustrates a process of fabrication of a device according to an embodiment of the present invention.

### DETAILED DESCRIPTION

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The present invention recognizes the need for structures, particularly MEMS and NEMS structures, characterized by high resonant frequencies and Q values and provides improved systems, structures, and techniques for achieving such high resonant frequencies and Q values. One important aspect of MEMS and NEMS systems recognized by various embodiments of the invention is the value of silicon on insulator, or SOI in MEMS and NEMS fabrication. The use of silicon provides a number of advantages. The processing of silicon has a long history, so that processing silicon to create various devices and structures is well understood. The use of SOI employs a single crystal material in the structure being created, and the use of a single crystal material leads to a higher frequency and a higher value of Q. In addition, the use of SOI in MEMS and NEMS structures lends itself easily to integration with SOI CMOS electronics and other electronics employing SOI.

The invention recognizes that various desirable characteristics can be achieved by subjecting a silicon structure to a tensile stress. A silicon structure subjected to a relatively high tensile stress exhibits relatively high resonant frequency and Q values, with higher levels of stress resulting in higher resonant frequency and Q values. Accordingly, various embodiments of the invention provide improved structures exhibiting tensile stress and improved techniques for fabricating and using such structures. Various embodiments of the present invention may comprise MEMS structures and techniques for their fabrication, but NEMS structures and techniques for fabricating such structures according to embodiments of the present invention are of particular interest because the small sizes and distances involved yield particular advantages, even over those available due to the sizes and distances involved in MEMS devices. For example, the tensile stress exerted on a silicon beam diminishes with the size of the beam and with the distance of points on the beam from the source of the stress. In addition, the tensile stresses that can be exerted on a cross section of a structure increase as the surface area to volume ratio of the structure increases.

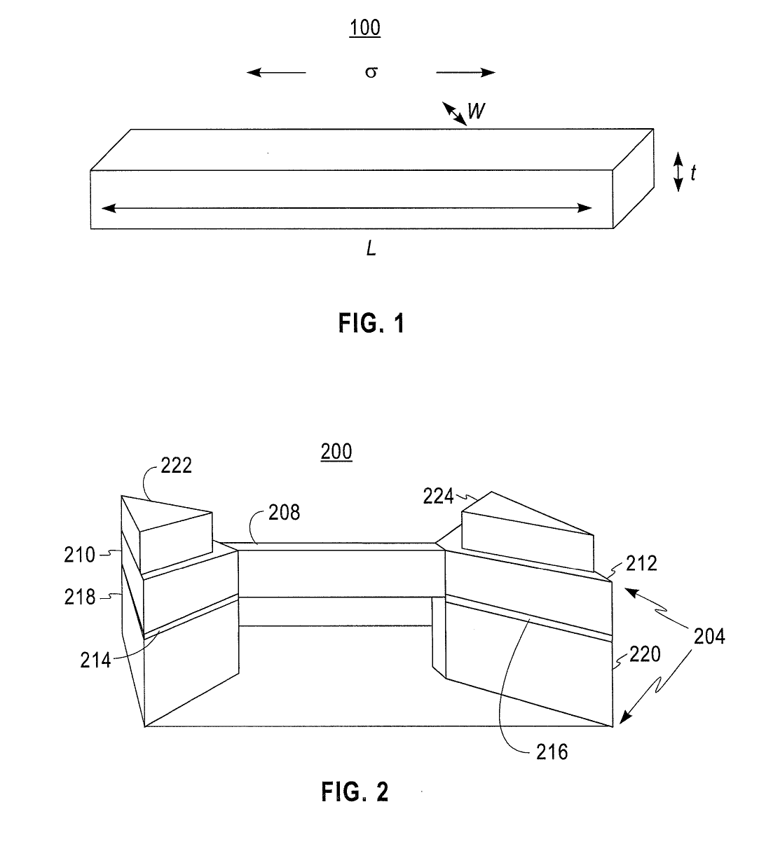

FIG. 1 illustrates an exemplary silicon on insulator (SOI) SOI beam 100, having dimensions L for length, w for width, and t for thickness. The resonant frequency, ω₀, of such a beam is

$${ω}_{0} = 1.028 ( \frac{t}{{L}^{2}} ) \sqrt{\frac{E}{ρ}} ,$$

where L is the beam length, t the beam thickness, E the Young's modulus, and ρ the density of the beam. Subjecting the beam to a tensile stress σ yields a resonant frequency ω₁, given by,

$${ω}_{1} = {ω}_{0} \sqrt{1 + B \frac{σ}{E} {( \frac{L}{t} )}^{2}}$$

where again, σ is the tensile stress and B is a constant of 0.295.

Subjecting an SOI beam to a specified degree of tensile stress can thus be seen to provide an easily computed resonant frequency. Various embodiments of the present invention therefore provide NEMS structures such as SOI beams, subjected to tensile stress chosen to provide desired frequencies and Q values and systems and techniques for fabricating structures in such a way as to create desired resonant frequencies and Q values without a need to make significant changes or variations to the structures themselves. For example, the resonant frequency for an unstressed Si beam with length, L, of 4 μM, thickness, t, of 50 nm, density, ρ, of 2.3 g/cm³ and Young's modulus, E, of 160 GPa, is calculated to be approximately 27 MHz. A tensile stress can be exerted on such a beam through the use of deposition regions deposited on anchor points anchoring the beam, as discussed in greater detail below. By creating such deposition regions by employing an overlying 400 nm thick, tensile film with a residual stress of 1 GPa, deposited over anchor points anchoring the beam, mechanical modeling results indicate that the stress imparted to the NEMS structure in an exemplary structure according to an embodiment of the invention, such as a geometry illustrated in FIG. 2, described below, can increase this resonant frequency by at least a factor of 5 to 134 MHz. This represents a substantial increase in resonant frequency, and can be achieved without changes to the dimensions of the structure itself. In addition, it is not necessary to only use the maximum tensile stress that can be achieved and, thus, the maximum increase in resonant frequency. Instead, the mechanisms for imparting the tensile stress to the beam can be chosen so as to achieve a degree of tensile stress that will achieve a specific desired resonant frequency of any value from the resonant frequency of an unstressed beam to the resonant frequency of a maximally stressed beam. It will be noted that the value of the residual stress of the tensile film does not translate directly to the same value of stress on the beam, because the stress exerted on the beam as a result of the presence of the deposition regions depends on a number of factors, such as the geometry of the deposition regions and their disposition with respect to the overall geometry of the structure in which the beam is disposed

An SOI beam is presented here by way of example, but it will be recognized that numerous other structures may be employed. For example, any number of structures, for example, rings and circles, may be employed as resonators in systems according to embodiments of the present invention, so long as the structures are suitable for use as resonators and are able to be disposed in such a way that they are subjected to the desired stress levels.

FIG. 2 illustrates an exemplary device 200, formed from a substrate 204 of silicon on insulator (SOI) material, which may comprise a substrate including a buried oxide (BOX) layer. The structure 202 includes a silicon beam 208 subjected to a desired tensile stress according to an exemplary embodiment of the invention. The silicon beam 208 extends between anchor points 210 and 212.

The anchor points 210 and 212 may be active silicon layers atop insulating layers 214 and 216, respectively, which themselves lie atop support points 218 and 220, respectively. As will be seen in greater detail in the following drawings and the discussion below, the anchor points 210 and the support points 212 may suitably be the remnants of deposition layers laid down as part of a buried oxide substrate.

Lying atop the anchor points 210 and 212 are dielectric deposition regions 222 and 224. The dielectric deposition regions 222 and 224 are of a material characterized by a high internal tension. Exemplary choices for the material comprising the deposition regions 222 and 224 are silicon nitride (SiN) and epitaxial silicon carbon (Si(C)). Silicon carbon is a material possessing a small fraction, approximately 2% or less, of carbon atoms that substitutionally reside in a silicon matrix that is epitaxially grown on the underlying silicon. Growing the Si(C) film epitaxially increases the stress that can be imparted to the beam 208 by the film. The internal tension of the deposition regions 222 and 224 causes the deposition regions 222 and 224 to exert a high compressive force on the anchor points 210 and 212, respectively. The compressive forces exerted on the anchor points 210 and 212 cause them, in turn, to exert a tensile force on the beam 208.

It will be recognized that there are a number of other films that can be used for this purpose. Optimal candidates would possess a high Young's modulus with respect to silicon, and a high residual stress. TiN, for example, would be a suitable choice, with a fabrication process being chosen that is appropriate for TiN, which might differ from that detailed below for SiN.

The internal tensile forces exhibited by the deposition regions 222 and 224, and therefore the compressive forces exerted by the deposition regions on the anchor points 210 and 212, varies in part with the thickness of the deposits 222 and 224. The maximum internal tensile force that can be achieved with a silicon nitride deposit such as the deposits 222 and 224 varies with the thickness of the deposit. Thus, different devices similar to the device 200 can be fabricated, with each device including a beam similar to the beam 208. Multiple devices can be fabricated, each with a substrate, anchor points, and beam substantially identical in composition, shape, and dimensions to equivalent elements of the device 200, but each device can, if desired, be fabricated to exhibit different characteristics, such as resonant frequencies and Q values, by varying the thicknesses and other characteristics of the deposits lying atop the anchor points 210 and 212.

MEMS and NEMS structures can be fashioned through various mass production techniques producing a large number of structures at a time. It is therefore possible to fabricate a large number of devices, or a system of devices, with different ones of the devices exhibiting different characteristics, with the only change from one device to another being a change in one or more of the composition, shape, treatment, and thicknesses of the deposits overlying the anchor points securing and exerting tension on a structure such as a beam similar to the beam 202.

In addition, sets of devices can be fabricated that differ between fabrication runs without altering the dimensions or other characteristics of devices other than by varying the deposits laid down atop the anchor points from one fabrication run to another.

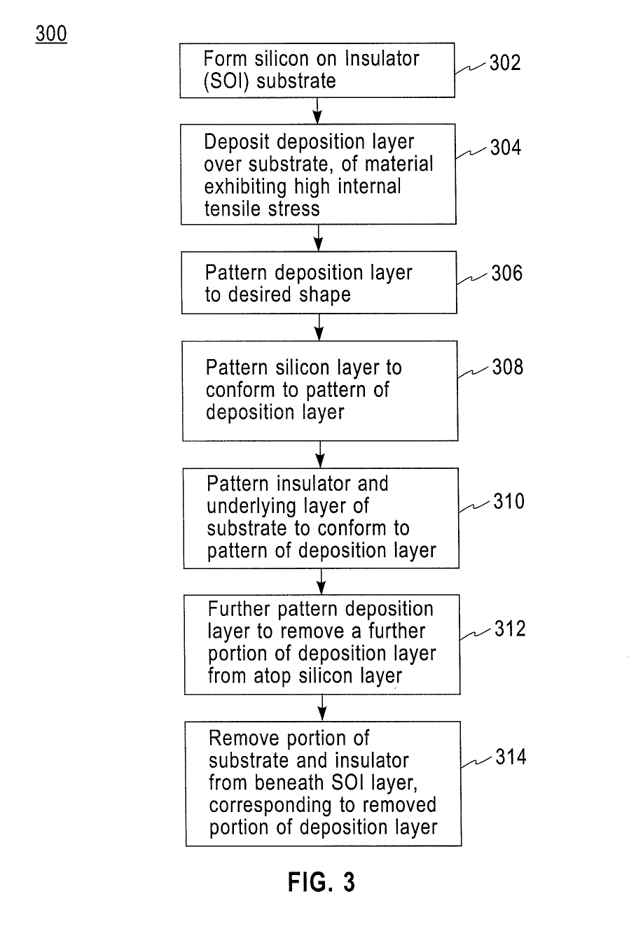

FIG. 3 illustrates a process 300 of device fabrication according to one exemplary and non-limiting embodiment of the present invention. At step 302, a silicon on insulator (SOI) substrate is formed. The SOI substrate may suitably be a buried oxide (BOX) substrate, which comprises a silicon wafer including an oxide layer within the wafer, such that the oxide layer acts as an insulator and isolates an active silicon layer atop the oxide layer from the material below the oxide layer.

At step 304, a deposition layer of a desired material exhibiting a high internal tensile stress is deposited over the substrate. This material is suitably a dielectric material, and may be SiN, Si(C), or any other suitable material. Suitable deposition techniques for this layer include chemical vapor deposition (CVD) and plasma enhanced chemical vapor deposition (PECVD) although numerous other techniques may be employed.

At step 306, the deposition layer is patterned to a desired shape. Exemplary patterning techniques that may be used include lithography and reactive ion etching. The shape of the pattern is chosen so as to create a deposition structure that will exert a desired tensile stress on the eventual structure created after the process 300 is completed, and may comprise two deposition regions joined by a bridge.

At step 308, a silicon layer of the substrate is patterned to conform to the pattern of the deposition layer. One non-limiting example is that of a pair of anchor points, joined by a bridge. At step 310, an underlying layer of the substrate is also patterned to conform to the pattern of the deposition layer. At this point, multiple layers of the structure being created conform to this pattern, so that in the present example, an SOI layer comprising two anchor points connected by a bridge lies atop a similarly shaped insulating layer, an underlying support structure lies beneath the insulating layer and a similarly shaped deposition layer lies atop the SOI layer.

At step 312, the deposition layer is further patterned to remove a further portion of the deposition layer lying atop the SOI layer. In the present example, the portion of the deposition layer lying atop the SOI beam is removed. At this point, in the present example, an SOI layer comprising two anchor points connected by an SOI beam lies atop a similarly shaped insulating layer, and a remnant of the deposition layer lies atop each of the anchor points. The deposition layer has been removed from atop the beam. Removal may be accomplished through any desired technique, such as lithography or reactive ion etching (RIE) that is selective to silicon and silicon dioxide. Alternatively, if the thickness of the deposition layer is much greater than the width of the beam, isotropic removal may be used.

At step 314, a portion of the material lying beneath the SOI layer is removed, corresponding to the removed portion of the deposition layer. In the present example, this is the portion of the insulating layer and the supporting layer lying beneath the SOI bridge, so that an SOI beam is released. In the present example, the structure at this point comprises two anchor points, each supported by a remnant of the underlying layer and insulated from the underlying layer by a remnant of the buried oxide layer. The anchor points are joined by an SOI beam, with a remnant of the deposition layer lying atop each of the anchor points.

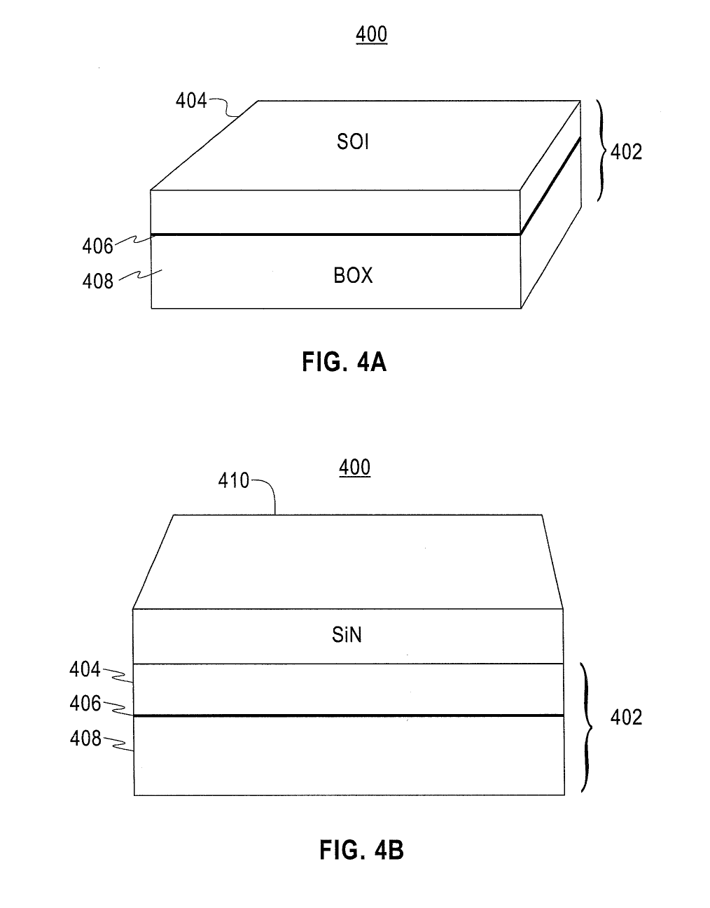

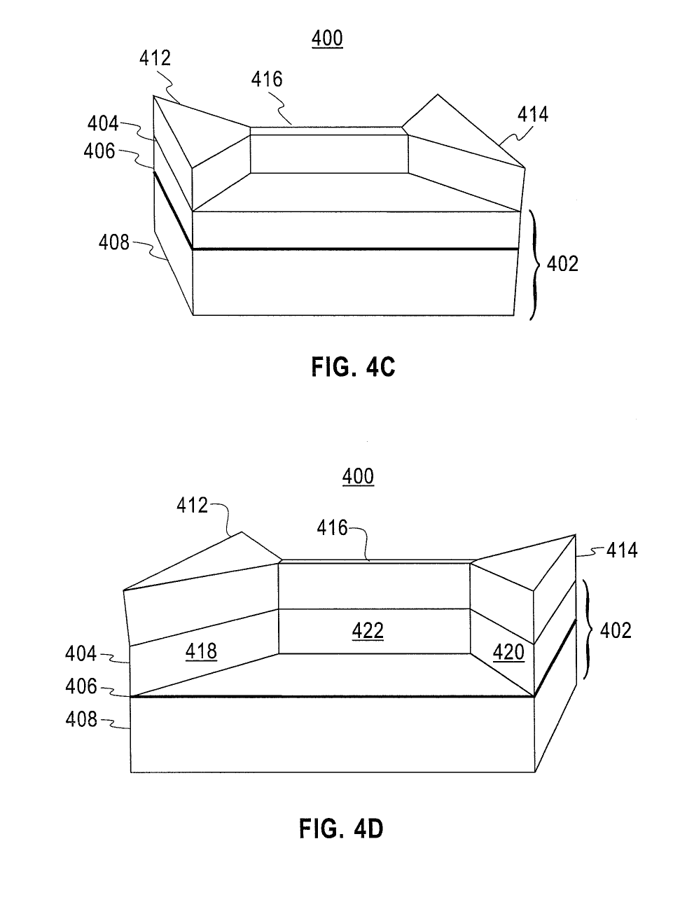

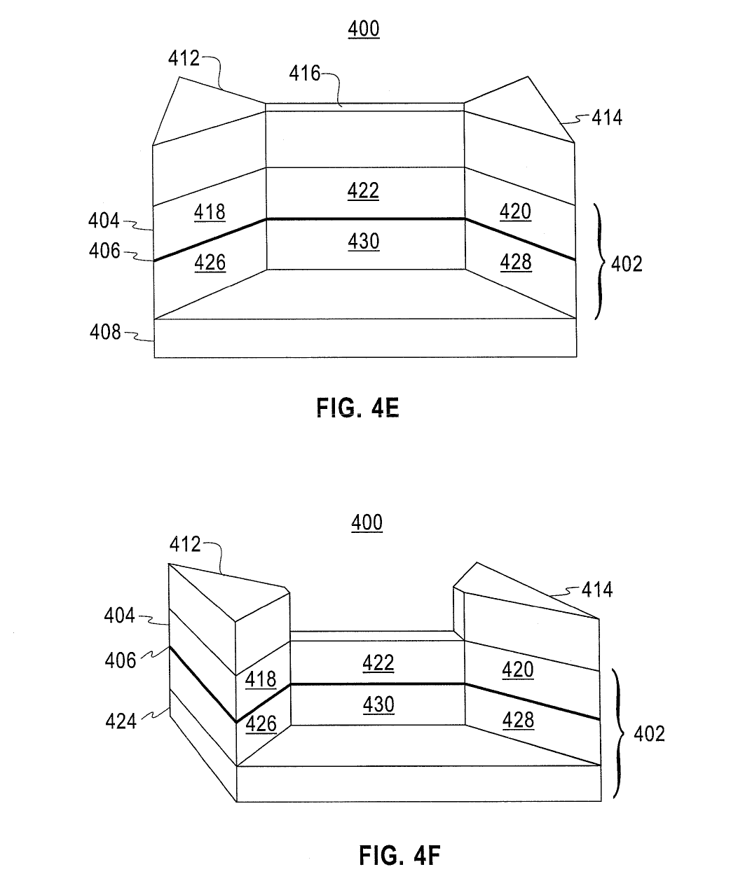

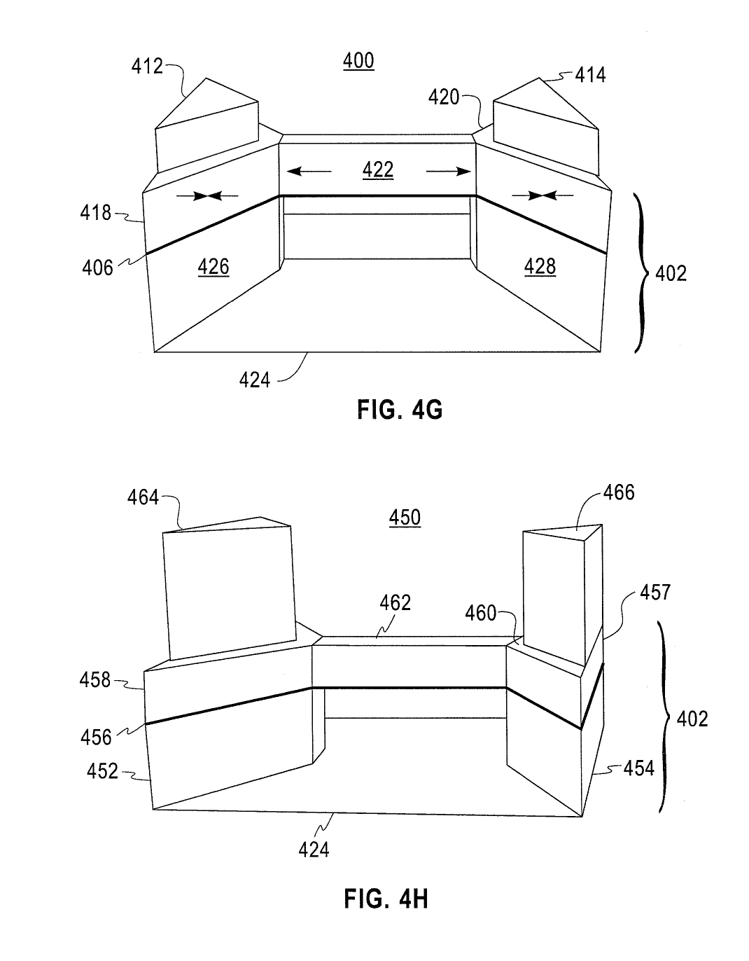

FIGS. 4A-4H illustrate various structures representing sequential stages of the construction of a device such as the exemplary device 200 of FIG. 2 by a process such as the exemplary process 300 of FIG. 3.

FIG. 4A illustrates an initial stage of the fabrication of a device 400 according to an embodiment of the present invention. As illustrated in FIG. 4A, the device 400 comprises an initial substrate 402 which in the present exemplary and non-limiting case comprises an SOI substrate. In the present exemplary embodiment, the SOI substrate is a BOX substrate, comprising an active silicon layer 404, an insulating oxide layer 406, and an underlying layer 408. The active silicon layer 404 is electrically isolated from the underlying layer 408 by the insulating oxide layer 406.

FIG. 4B illustrates a subsequent stage of construction of the device 400. The substrate 402, comprising the active silicon layer 404, insulating layer 406, and underlying layer 408 can be seen, in addition to a deposition layer 410, which in the present case is SiN. The SiN layer exhibits an internal tensile stress that creates a strain field in the active silicon layer lying beneath it. The strain field is at its maximum at the edge of the deposition layer and extends some distance beyond the edge.

FIG. 4C illustrates a subsequent stage of fabrication, showing patterning of the deposition layer 410. Material has been removed from the deposition layer 410 so that first and second deposition regions 412 and 414 have been formed, connected by a deposition bridge 416. Patterning of the deposition layer does not alter its internal tensile stress, and the strain field imparted to the active silicon layer depends on the internal tensile stress of the deposition layer and the geometry of the active silicon layer.

FIG. 4D illustrates a further stage of fabrication, showing patterning of the active silicon layer 404 and the insulating layer 406. Depending on the particular patterning technique used, the active silicon layer 404 and the insulating layer 406 may be patterned simultaneously or only the active silicon layer 404 may be patterned. The particular order of patterning is not important, and depends on the particular technique used at each patterning stage. At this stage, two active silicon anchor points 418 and 420 have been formed, supporting the first and second deposition regions 412 and 414, with an SOI bridge 422 running between the anchor points 418 and 420 and supporting the deposition bridge 416. Remnants of the insulating layer 406 electrically isolate the anchor points 418 and 420 and the SOI bridge 422 from the underlying layer 408. The strain field imparted to the active silicon layer by the deposition regions 412 and 414 is therefore at a maximum at the edges of the regions 412 and 414, and extends some distance beyond the edges of the regions 412 and 414, that is, some distance into the SOI bridge 422.

FIG. 4E illustrates a still further stage of fabrication, showing patterning of the underlying layer 408. Material has been removed from the underlying layer 408 to conform to the patterning of the SOI layer 404 and the deposition layer 410, forming a lower underlying layer 424, supporting two isolated support points 426 and 428, connected by an underlying support bridge 430. The remainder of the insulating layer 406 separates the support points 426 and 428 and the support bridge 430 from the anchor points 418 and 420 and the SOI bridge 422.

FIG. 4F illustrates a still further stage of fabrication of the device 400. The deposition bridge 416 has been removed, so that the deposition regions 412 and 414 are now islands.

FIG. 4G illustrates a further stage of construction of the device 400. The support bridge 430 has been removed, along with the portion of the insulating layer 406 that formerly isolated the SOI bridge 422 from the support bridge 430. The SOI bridge 422 may now be more accurately referred to as an active silicon beam 422, and the remnants of the insulating layer 406 are now islands isolating the anchor points 418 and 420 from the support points 426 and 428.

The deposition regions 412 and 414 are characterized by a high internal tension, exerting a compressive force on the anchor points 418 and 420. Because the anchor points 418 and 420 are affixed to opposite ends of the active silicon beam 422, the compression of the anchor points 418 and 420 subjects the active silicon beam 422 to a tensile stress. As noted above, the tensile stress to which the beam 422 is subjected alters the resonant frequency of the beam 422 as compared to the resonant frequency of a beam of identical dimensions in the absence of tensile stress, and the resonant frequency can be determined using the formulas presented above.

FIG. 4H illustrates an alternative device 450, representing an alternative embodiment of the device 400, substantially identical to the device 400 with the exception of the thickness of the deposition layers used in the device 450. The device 450 may rest on the lower underlying layer 424, because the device 400 and the device 450 may be two of many devices that may be fabricated using a single substrate, so that the lower underlying layer 424 extends to support many devices. The device 450 comprises support points 452 and 454, insulating islands 456 and 457, and anchor points 458 and 460 anchoring an active silicon beam 462. Lying atop the anchor points 458 and 460 are deposition islands 464 and 466. The various elements of the device 450 may suitably be substantially identical in composition, shape, and dimensions to those of the corresponding elements of the device 450, with the exception of the deposition islands 464 and 466, which are substantially thicker than the deposition islands 414 and 416.

This comparatively greater thickness of the deposition islands 464 and 466 allows for a greater maximum tensile force within the deposition islands 464 as opposed to the deposition islands 414 and 416, causing them to exert a higher compressive force on the anchor points 458 and 460, as compared with the compressive force exerted by the deposition islands 414 and 416 on the anchor points 418 and 420. This greater compressive force results in a greater tensile stress on the beam 462 as compared to the beam 422, and causing the SOI beam 462 to exhibit a higher resonant frequency than does the SOI beam 410. Different deposition thicknesses can be used on various structures such as the structures 400 and 450, with each deposition thickness for a structure being chosen based on the desired tensile stress that is to be imparted by the deposits. As provided by the formula presented above, the tensile stress that can be imparted by the deposits provides for a resonant frequency and other characteristics influenced by tensile stresses experienced by elements of the structure.

The thickness of an SiN layer used in an NEMS or MEMS structure can range from approximately 10 nm to approximately 500 nm. An SiN layer or deposit laid down on an SOI structure produces a strain field that has a maximum at the edge of the SiN layer or deposit and extends for some distance beyond the edge, depending on the geometry of the structure on which the SiN deposit or layer is placed. Careful design of the strain field, together with the geometry of the anchor points and other characteristics of a structure such as the devices 400 and 450, allows for application of precise tensile stress on elements such as the beams 422 and 462.

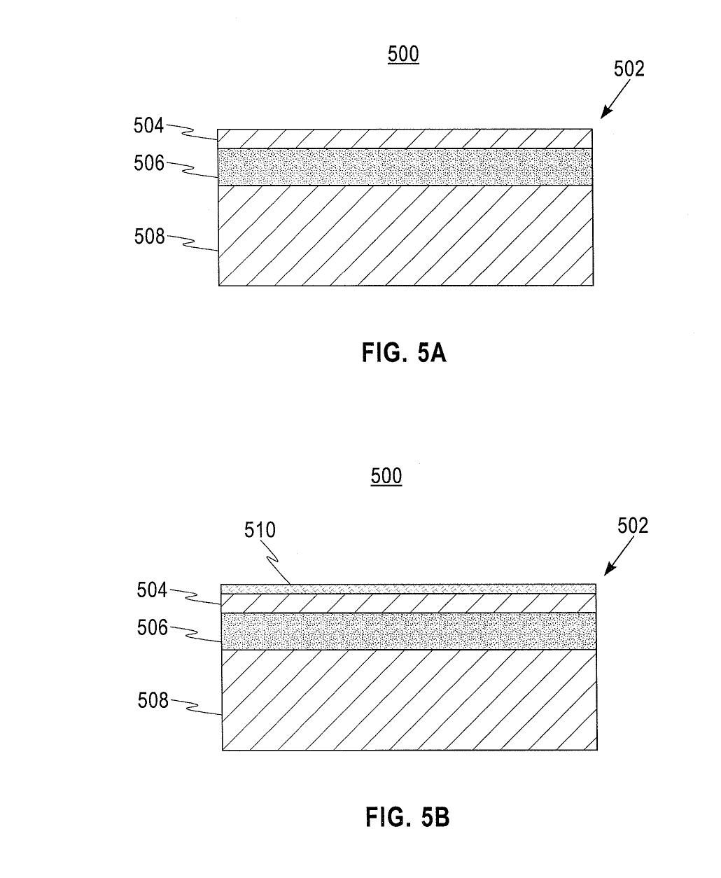

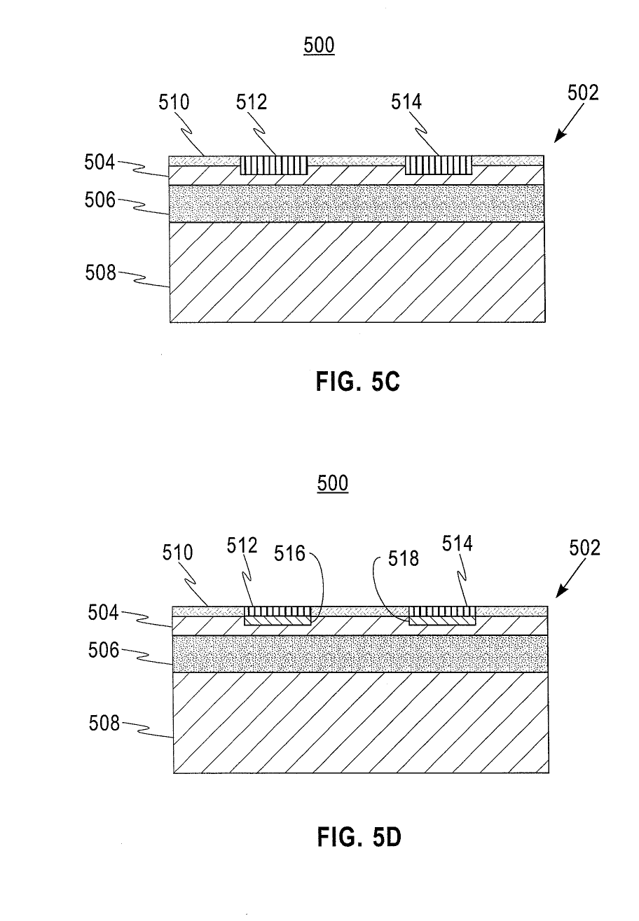

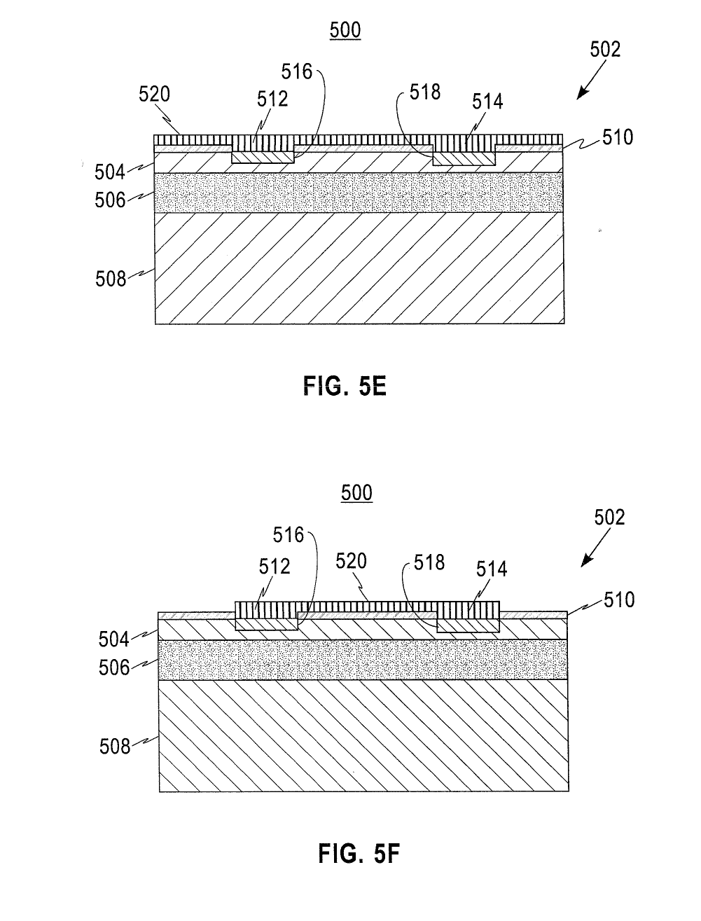

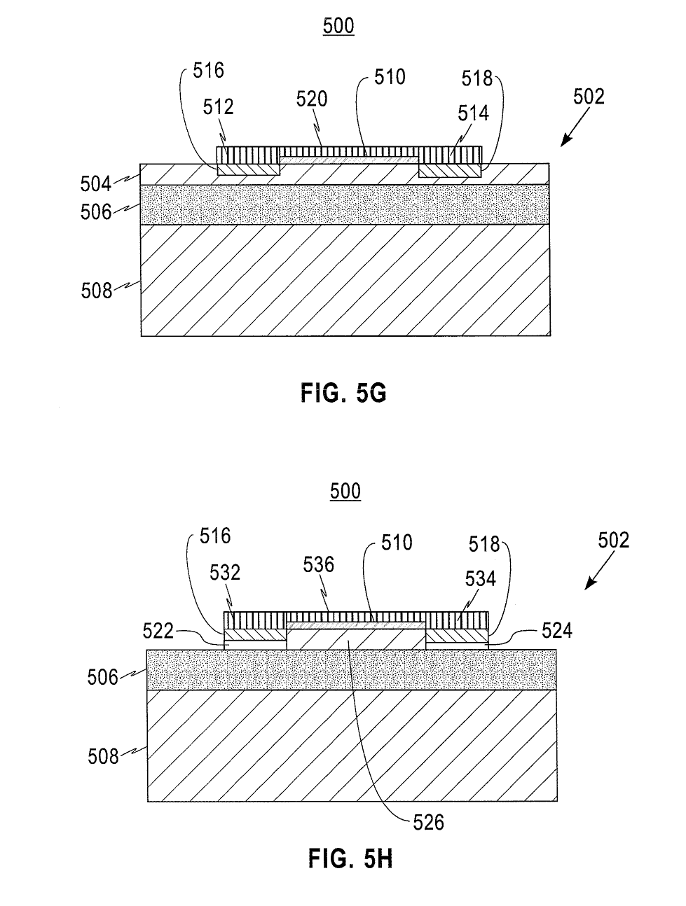

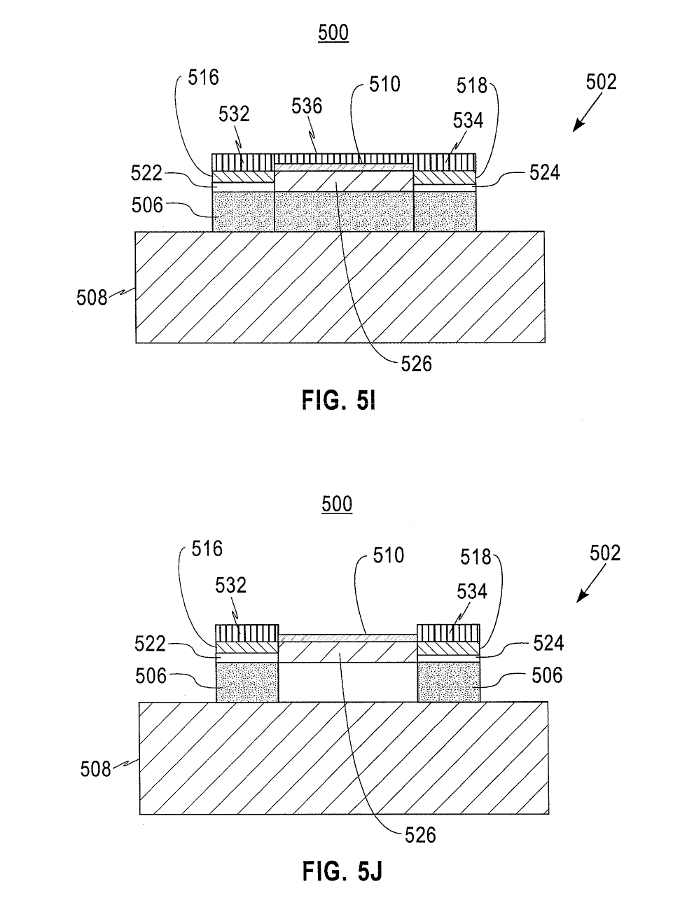

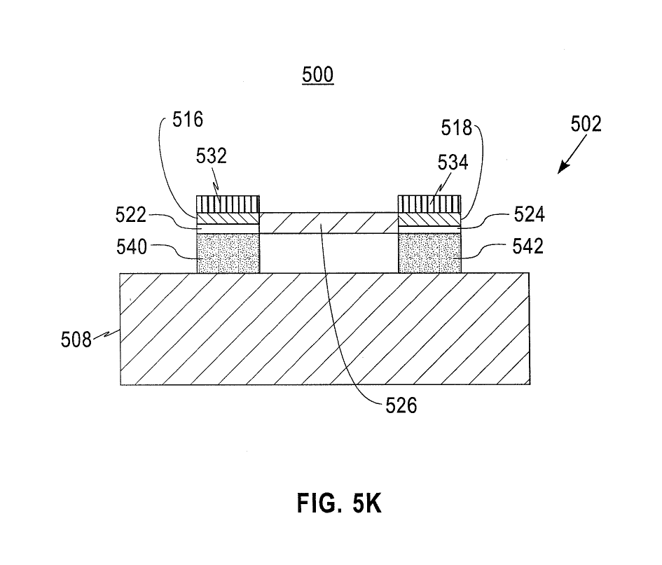

FIGS. 5A-5K illustrate various stages of fabrication of a device 500 according to an exemplary embodiment of the present invention. The goal of the fabrication of the device 500 is a device comprising a silicon beam subjected to tensile stress chosen to achieve desired characteristics.

FIG. 5A illustrates a substrate 502 on which the device 500 is fabricated. The substrate 502 is a buried oxide (BOX) wafer, with an active silicon layer 504, an insulating oxide layer 506, and an underlying silicon layer 508. FIG. 5B illustrates a further stage of fabrication of the device 500, after deposit of an upper oxide layer 510.

FIG. 5C illustrates a further state of fabrication of the device 500. Etching has been performed on the upper oxide layer 510 and the active silicon layer 504, using lithography, oxide reactive ion etching, and silicon recession, creating receptacles 512 and 514. The receptacles 512 and 514 extend through the upper oxide layer 510 and into the active silicon layer 504.

FIG. 5D illustrates a further stage of fabrication of the device 500. Embedded silicon carbon (eSi(C)) deposits 516 and 518 have been placed in the receptacles 512 and 514, extending nearly to the top of the active silicon layer 504. When eSi(C) is used with SOI, the thickness of the eSi(C) needs to be at least slightly less than the thickness of the SOI layer. The eSi(C) deposits illustrated here impart stress to the SOI.

FIG. 5E illustrates a still further stage of fabrication of the device 500. A silicon nitride (SiN) layer 520 has been deposited. The SiN exhibits a high internal tensile stress. The SiN layer 520 overlies the upper oxide layer 510, and extends into the receptacles 512 and 514 to the level of the top of the eSi(C) deposits 516 and 518. The thickness of the portion of the SiN layer 520 extending into the receptacles 512 and 514 depends on the thickness of the upper oxide layer 510. It will be noted that the example here shows the use of both eSi(C) and SiN, but only one material need be used.

FIG. 5F illustrates a further stage of fabrication of the device 500. The portion of the SiN layer 520 extending beyond the receptacles 512 and 514 has been removed using lithography and SiN reactive ion etching. The removal of the SiN layer 520 extending beyond the receptacles 512 and 514 is shown here by way of illustration, and it is not necessary to remove any or all of this portion of the SiN layer. Removing SiN material beyond the receptacles 512 and 514 removes SiN stressor material, which reduces the overall force that will be imparted to the eventual silicon beam. If the maximum possible stress is to be achieved, leaving in place the portion of the layer beyond the receptacles 512 and 514 will be advisable. However, portions of the SiN material may be removed so as to achieve the specific tensile stress desired. Thus, depending on the design of the device 500, the dimensions of the various components, and the materials used, more or less material may be removed, and a shape imparted to the remaining material to achieve the desired tensile stress.

FIG. 5G illustrates a further stage of fabrication of the device 500, showing that oxide reactive ion etching has been used to remove the portion of the upper oxide layer 510 extending beyond the receptacles 512 and 514, and FIG. 5H illustrates a still further stage of fabrication of the device 500, showing that silicon reactive ion etching has been used to remove the portion of the active silicon layer 504 extending beyond the receptacles 512 and 514. The removal of the entire portion extending beyond the receptacles 512 and 514 is illustrated and described by way of illustration, but it will be recognized that removing the portions of the active silicon layer adjacent to the eSi(C) allows relaxation of the eSi(C) because the constraint imposed by the silicon is diminished. Therefore, as is the case with the SiN layer, adjustment of the amount and shape of the portions of the active silicon layer that are removed adjusts the tensile stress imparted to the eventual silicon beam.

At this point, the device 500 comprises the underlying silicon layer 508, the insulating oxide layer 506, and the remainder of the active silicon layer 504. The active silicon layer 504 has been etched away so that what remains are anchor points 522 and 524, affixed to a silicon on insulator (SOI) bridge 526. Overlying the anchor points 522 and 524 are eSi(C) regions 516 and 518, and overlying the eSi(C) regions are SiN regions 532 and 534. An SiN bridge 536 extends between the SiN regions 532 and 534, separated from the SOI bridge by the remainder of the upper oxide layer 510.

FIG. 5I illustrates a further stage in the fabrication of the device 500. The portion of the insulating oxide layer 506 extending beyond the receptacles 512 and 514 has been removed using buried oxide reactive ion etching. FIG. 5J illustrates a still further stage in the fabrication of the device 500. The SiN bridge 536 has been removed.

FIG. 5K illustrates a further stage in the fabrication of the device 500, showing the device 500 as completed. Oxide pull-back has been performed, suitably using hydrofluoric acid vapor, so that portions of the oxide layer have been removed to free what is now an active silicon beam 526. The device 500 now comprises the underlying silicon layer 508, on which rest insulating support regions 540 and 542. The insulating support regions 540 and 542 are what remain of the insulating layer 506. Anchor points 522 and 524, which are active silicon regions overlying the support regions 540 and 542, are present, with the active silicon beam 526 extending between them. Lying atop the anchor points 522 and 524 are the eSi(C) regions 516 and 518, and lying atop the eSi(C) regions 516 and 518 are the SiN regions 532 and 534. The SiN regions 532 and 534 have a thickness based in part on the thickness of the upper oxide layer 510 which was originally deposited, but is now removed. Looking again at FIGS. 5C and 5D, it is clear that the receptacles 512 and 514 allowed entry of SiN material, and the lower boundary of the SiN material in the receptacles 512 and 514 was formed by the eSi(C) regions 516 and 518. The SiN material fills the receptacles 512 and 514 to the boundary formed by the regions 516 and 518, and the depth of the receptacles 512 and 514 to this boundary is defined by the thickness of the upper oxide layer 510. The SiN regions 532 and 534 therefore have a thickness equal to that of the SiN layer lying atop the upper oxide layer 510, plus the thickness of the upper oxide layer 510 itself.

The presence of the SiN regions 532 and 534 and the eSi(C) regions 516 and 518 results in a tensile loading of the active silicon beam 522. The SiN regions 532 and 534 and the eSi(C) regions 516 and 518 exhibit a high internal tensile stress, which couples a compressive force to the anchor points 522 and 524. The anchor points 522 and 524 are at opposite ends of the beam 526, and the compressive force exerted on the anchor points 522 and 524 causes them to exert opposite tensile forces on the beam 526.

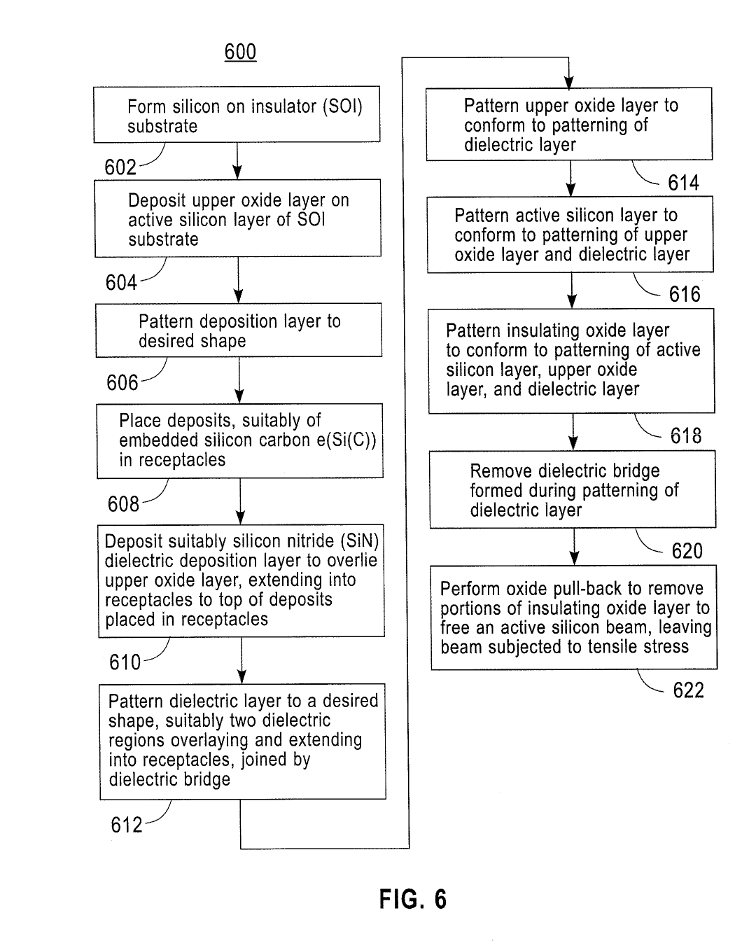

FIG. 6 illustrates the steps of a process 600 of device fabrication according to an embodiment of the present invention. At step 602, a silicon on insulator substrate is formed. The substrate may suitably be a buried oxide substrate, comprising an active silicon layer, an insulating oxide layer, and a lower silicon layer. At step 604, an upper oxide layer is formed on the active silicon layer. At step 606, receptacles are formed in the upper oxide layer. The receptacles suitably extend into the active silicon layer. Formation of the receptacles may be achieved by etching, using lithography, oxide reactive ion etching, and silicon recession, to creating receptacles that extend through the upper oxide layer and into the active silicon layer. At step 608, deposits, suitably of embedded silicon carbon (eSi(C)) are placed in the receptacles. The deposits suitably extend to the top of the active silicon layer.

At step 610, a dielectric layer, suitably of silicon nitride (SiN) is deposited to overlie the upper oxide layer and extending into the receptacles to the level of the top of the deposits that have been placed in the receptacles. The thickness of the portion of the layer extending into the receptacles depends on the thickness of the upper oxide layer. At step 612, the dielectric layer is patterned using lithography and SiN reactive ion etching. Portions of the dielectric layer are removed so that what remains of the dielectric layer are two dielectric regions over and extending into the receptacles, with the dielectric regions being joined by a dielectric bridge. At step 614, the upper oxide layer is patterned to conform to the patterning of the dielectric layer, suitably using reactive oxide etching.

At step 616, the active silicon layer is also patterned, so that it conforms to the patterning of the dielectric layer and the upper oxide layer, suitably using silicon reactive ion etching. At this point, the underlying silicon layer, the insulating oxide layer, and the remainder of the active silicon layer are present. The active silicon layer has been etched away so that what remains are anchor points joined by a silicon on insulator (SOI) bridge. Overlying the anchor points are eSi(C) regions and overlying the eSi(C) regions and the SOI bridge are the dielectric regions and the dielectric bridge.

At step 618, the insulating oxide layer is similarly patterned to conform to the patterning of the active silicon layer, the upper oxide layer, and the dielectric layer, suitably using buried oxide reactive ion etching. At step 620, the dielectric SiN bridge is removed.

Finally, at step 622, oxide pull-back is performed, suitably using hydrofluoric acid vapor, so that portions of the insulating oxide layer are removed to free what is now an active silicon beam. The finished device comprises the underlying silicon layer, on which rest insulating support regions. The insulating support regions are what remain of the insulating layer. Anchor points, which are active silicon regions overlying the support regions, are present, with the active silicon beam extending between them. Lying atop the anchor points are the eSi(C) regions, and lying atop the eSi(C) regions are SiN regions. The SiN regions have a thickness based in part on the thickness of the upper oxide layer which was originally deposited, but is now removed. The SiN regions exert a compressive force on the anchor points, with the compressive force exerted by each of the SiN regions depending at least in part on its thickness, and this compressive force causes the anchor points to exert opposing forces on the active silicon beam, subjecting the beam to a tensile stress and causing the beam to take on properties such as resonant frequency and Q factor based on a combination of the dimensions of the beam and the tensile stress.

### ADVANTAGES OF THE INVENTION

Various embodiments of the present invention improve over the prior art by providing for mechanisms to regulate important characteristics of MEMS and NEMS devices using a convenient addition that does not require any changes to the dimensions or structure of a device, and allowing the specific characteristics of the device can be varied as needed by varying the addition rather than the dimensions or structure of the device. The tensile stress on a device component, such as an SOI beam, can be adjusted to provide a desired resonant frequency, Q factor, or other characteristics, by placing deposits at appropriate points on the device that exert forces that can be regulated by varying the deposits.

The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated.

1. A structure characterized by tensile stress on selected components, comprising:
a beam extending between first and second anchor points;
a first deposition region overlying the first anchor point and a second deposition region overlying the second anchor point, the first and second deposition regions respectively exerting a compressive force on the first and second anchor points, such that each of the first and second anchor points exerts a force on the beam, wherein the forces exerted by the first and second anchor points combine to subject the beam to a tensile stress.

2. The structure of claim 1, wherein the first and second anchor points and the beam comprise a monolith.

3. The structure of claim 1, wherein the first and second anchor points comprise portions of an active silicon layer of the structure.

4. The structure of claim 2, wherein the first and second deposition regions comprise portions of a deposition layer deposited over the active silicon layer.

5. The structure of claim 4, wherein each of the first and second deposition regions exhibits an internal tensile stress based at least in part on its thickness.

6. The structure of claim 4, wherein each of the first and second deposition regions exhibits an internal tensile stress based at least in part on its shape.

7. The structure of claim 5, wherein the first and second deposition regions comprise silicon nitride.

8. The structure of claim 5, wherein the first and second anchor points and the beam comprise silicon on insulator (SOI).

9. The structure of claim 5, wherein the substrate comprises a buried oxide layer.

10. The structure of claim 5, wherein the first and second deposition regions have a thickness chosen based on a desired resonant frequency of the beam.

11. The structure of claim 5, wherein the first and second deposition regions comprise embedded silicon carbon.

12. A method for fabricating a structure characterized by tensile stress on selected components, comprising:
depositing a deposition layer on an active semiconductor layer;
removing portions of the deposition layer so as to form a desired pattern in the deposition layer;
removing portions of the active semiconductor layer and an underlying substrate electrically insulated from the active semiconductor layer to form a pattern of the active semiconductor layer and the substrate conforming to the pattern of the deposition layer;
removing a portion of the deposition layer such that portions of the deposition layer remaining on the active semiconductor layer exhibit internal tensile stress so as to subject each of first and second regions of the semiconductor layer to a compressive stress; and
removing a portion of the substrate such that a first and second anchor point of the active semiconductor layer are connected by a beam subjected to tensile stress by the first and second regions of the semiconductor layer.

13. The method of claim 12, wherein the pattern of the deposition layer comprises first and second deposition regions joined by a bridge.

15. The method of claim 12, wherein the deposition layer comprises silicon nitride.

16. The method of claim 12, wherein the active semiconductor layer comprises silicon on insulator.

17. The method of claim 12, wherein the step of depositing the deposition layer comprises depositing the deposition layer in a thickness chosen based on a tensile stress to be exerted on the beam.

18. The method of claim 12, wherein the active semiconductor layer is electrically insulated from the underlying substrate by a buried oxide layer.

19. A resonant transducer, comprising:
a base silicon layer;
first and second electrically insulating support points overlying the base silicon layer;
first and second active silicon anchor points overlying the first and second insulating support points, respectively;
a silicon beam joining the first and second active silicon anchor points; and
first and second deposition regions disposed to exert a compressive force on the anchor points such that the anchor points exert opposing forces on the active silicon beam to subject the active silicon beam to a tensile stress.

20. The resonant transducer of claim 19, wherein the first and second deposition regions are of a thickness chosen based at least in part on a desired tensile stress to which the active silicon beam is to be subjected.

21. The resonant transducer of claim 19, wherein the first and second deposition regions comprise one or more of silicon nitride and embedded silicon carbon.
